(19) United States
(12) Patent Application Publication
(10) Pub. No.: US 2024/0162262 A1
(43) Pub. Date: May 16, 2024

(54) BACKSIDE ILLUMINATION IMAGE SENSOR AND METHOD OF FORMING THE SAME

(71) Applicants: Semiconductor Manufacturing International (Beijing) Corporation, Beijing (CN); Semiconductor Manufacturing International (Shanghai) Corporation, Shanghai (CN)

(72) Inventors: Huike WANG, Beijing (CN); Zhigao WANG, Beijing (CN)

(21) Appl. No.: 18/507,696

(22) Filed: Nov. 13, 2023

(30) Foreign Application Priority Data
Nov. 16, 2022 (CN) 202211435752.1

(51) Int. Cl. H01L 27/146; H01L 23/00

(52) U.S. Cl. CPC H01L 27/14629; H01L 24/08; H01L 27/1463; H01L 27/14634; H01L 27/14636; H01L 27/14685; H01L 27/1469; H01L 2224/08145

(57) ABSTRACT

A backside illuminated (BSI) image sensor includes: an array substrate containing one or more photosensitive devices and including a first surface; a mirror layer disposed at a side of the first surface of the array substrate and electrically insulted from the one or more photosensitive devices; and an interconnection structure layer disposed at a side of the mirror layer facing away from the array substrate, electrically connected to the one or more photosensitive devices, and electrically insulated from the mirror layer.

### CROSS-REFERENCE TO RELATED APPLICATION

This application claims priority to Chinese Patent Application No. 202211435752.1, filed on Nov. 16, 2022, and the entire content of which is incorporated herein by reference.

### TECHNICAL FIELD

The present disclosure relates to the technical field of semiconductor manufacturing technology, and more particularly, to a backside illumination (BSI) image sensor and a method of forming the back-lit image sensor.

### BACKGROUND

Direct time-of-flight (DTOF) measurement is a commonly used optical ranging method and is widely used in optical ranging systems such as lidar. In the DTOF measurement method, an intensity of a pulse light signal is not recorded. Only time difference between emission and detection of the pulse light signal is recorded. The time difference between the emission and detection of the pulse light signal can be directly converted into distance information.

The core photosensitive device of the DTOF measurement method is a single photon avalanche diode (SPAD). A single-photon detector is a diode that operates in a reverse avalanche breakdown region, and can detect a single-photon signal by triggering an avalanche breakdown with the photon.

The single photon detector requires high photosensitivity efficiency. In a front side illumination (FSI) mode, the single photon detector often has an unsatisfactory light incident efficiency due to light blockage by a front interconnection structure layer. In a backside illumination (BSI) mode, an epitaxial layer where the single photon detector is located can be thinned from the back to a thickness of a few microns to reduce a length of an incident light path. At the same time, a back interconnection structure layer blocks interference. Thus, the light incident efficiency can be substantially improved.

In the BSI mode, an array substrate is thin after being thinned. Thus, the array substrate needs to be attached to a carrier. If a logic processing circuit for processing a photoelectric signal is disposed at the carrier thereunder, an array density of the array substrate can be substantially improved.

When the array substrate and logic processing circuit are sliced and integrated, an upper wafer and a lower wafer need to be electrically connected. For example, a more advanced process of hybrid bonding may be used to bond the two wafers. The hybrid bonding provides a bonding surface with a mixture of copper and dielectric (Cu/SiO2), which facilitates simultaneous metal-to-metal boding and dielectric-to-dielectric bonding between the two wafers. Thus, not only an inter-chip interconnection area can be reduced due to direct interconnection of metal layers, but also an RC delay can be substantially reduced.

However, the photon detection efficiency of existing BSI image sensors is low. As the photon detection efficiency increases, substantial crosstalk may easily occur between adjacent photosensitive devices.

### SUMMARY

One aspect of the present disclosure provides a backside illuminated (BSI) image sensor. The BSI image sensor includes: an array substrate containing one or more photosensitive devices and including a first surface; a mirror layer disposed at a side of the first surface of the array substrate and electrically insulted from the one or more photosensitive devices; and an interconnection structure layer disposed at a side of the mirror layer facing away from the array substrate, electrically connected to the one or more photosensitive devices, and electrically insulated from the mirror layer.

Another aspect of the present disclosure provides a method of forming a backside illuminated (BSI) image sensor. The method includes: forming an array substrate containing one or more photosensitive devices and including a first surface; forming a mirror layer over the first surface of the array substrate; and forming an interconnection structure layer over the mirror layer, the interconnection structure layer being electrically connected to the one or more photosensitive devices.

### BRIEF DESCRIPTION OF THE DRAWINGS

FIG. 1 is a cross-sectional view of an exemplary backside illuminated image sensor according to some embodiments of the present disclosure.

FIGS. 2-9 are cross-sectional views showing various stages of a process of forming an exemplary BSI image sensor according to some embodiments of the present disclosure.

### DETAILED DESCRIPTION OF THE EMBODIMENTS

In order to make the objectives, technical solutions, and advantages of the present disclosure clearer, the present disclosure will be further described in detail below with reference to the accompanying drawings. Obviously, the described embodiments are only some of the embodiments of the present disclosure, not all of the embodiments. Based on the embodiments of the present disclosure, all other embodiments obtained by those of ordinary skill in the art without creative efforts shall fall within the scope of the present disclosure.

As described in the background, the photon detection efficiency of existing BSI image sensors is low, and substantial crosstalk may easily occur between adjacent photosensitive devices. A BSI image sensor is used to analyze the reasons why the photon detection efficiency is low and the substantial crosstalk may easily occur between adjacent photosensitive devices.

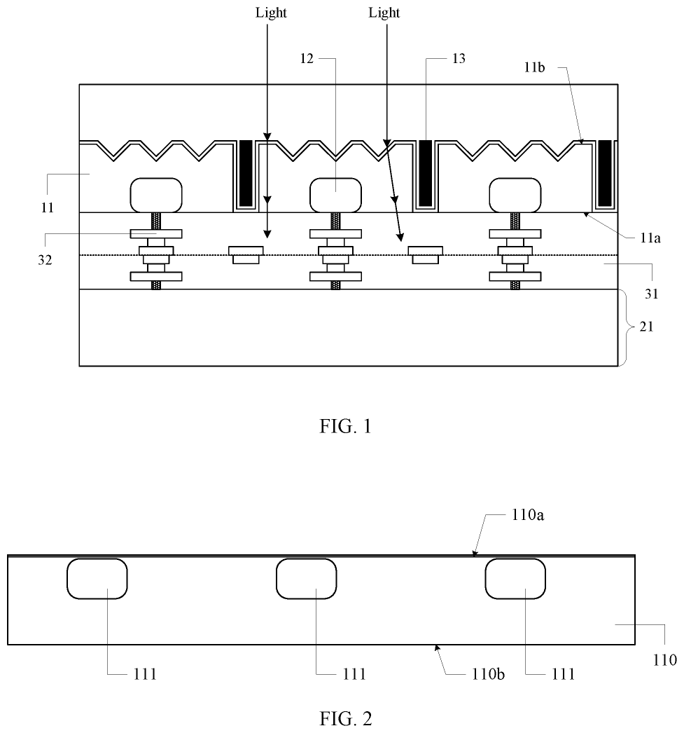

FIG. 1 is a cross-sectional view of an exemplary backside illuminated image sensor according to some embodiments of the present disclosure.

As shown in FIG. 1, the BSI image sensor includes: an array substrate 11 containing one or more photosensitive devices 12, a logic substrate 21 disposed at a side of the array substrate 11, an interconnection structure layer 31 disposed at the array substrate 11 and sandwiched between the array substrate 11 and the logic substrate 21. The interconnection structure layer 31 is electrically connected to both the array substrate 11 and the logic substrate 21 to achieve electrical interconnection between the array substrate 11 and the logic substrate 21.

The array substrate 11 has a first surface 11a facing toward the interconnection structure layer 31 and a second surface 11b opposite to the first surface 11a. The second surface 11b is a surface for receiving illumination. A light absorption layer (not shown) is provided on the second surface 11b, thereby improving light absorption of the BSI image sensor by an order of magnitude.

However, when photons are incident on a pixel area between adjacent isolation structures 13, some of the photons will pass through the array substrate 11 and fail to enter the one or more photosensitive devices 12 to cause avalanche breakdown, thereby affecting the improvement of the photon detection efficiency.

In addition, some of the photons transmitted through the array substrate 11 will be projected onto a first metal layer 32 of the interconnection structure layer 31 that is closest to each of the one or more photosensitive devices 12, and will be reflected by the first metal layer 32.

On the other hand, because the first metal layer 32 is a part of the interconnection structure layer 31 and performs an electrical function, a certain distance needs to be maintained between the first metal layer 32 and the corresponding photosensitive device 12 to ensure stability of its electrical performance.

A relatively large distance between the first metal layer 32 and the corresponding photosensitive device 12 will cause the photons projected onto the first metal layer 32 to be reflected to adjacent pixel areas, thereby causing crosstalk between adjacent pixel areas, and affecting a signal-to-noise ratio (SNR) of the BSI image sensor.

To solve this technical problem, the present disclosure provides a BSI image sensor. A mirror layer is separately provided between the interconnection structure layer and the array substrate to reflect light, thereby improving the photon detection efficiency. Moreover, the mirror layer is in contact with the interconnection structure layer and the plurality of photosensitive devices to electrical insulation in-between, which can effectively reduce the distance between the mirror layer and the plurality of photosensitive devices. The mirror layer can be as close as possible to the plurality of photosensitive devices, which can effectively reduce crosstalk between adjacent photosensitive devices.

To make the above objectives, features and advantages of the present disclosure more obvious and understandable, various embodiments of the present disclosure will be described in detail below with reference to the accompanying drawings.

FIGS. 2-9 are cross-sectional views showing various stages of a process of forming an exemplary BSI image sensor according to some embodiments of the present disclosure.

Referring to FIG. 2, an array substrate 110 is formed. The array substrate 110 includes a plurality of photosensitive device 111s therein. The array substrate 110 further includes a first surface 110a.

The array substrate 110 is used to form and accommodate the plurality of photosensitive devices 111.

The array substrate 110 further includes a substrate (not shown) and the plurality of photosensitive devices 111 embedded in the substrate. The substrate is a base platform for subsequent processes. The material of the substrate is selected from monocrystalline silicon, polycrystalline silicon, or amorphous silicon. The material of the substrate may also be selected from silicon, germanium, gallium arsenide, or silicon germanium compounds. The substrate may also be selected from a structure with an epitaxial layer or silicon on an epitaxial layer. The substrate may also be made of other semiconductor materials, and the present disclosure does not impose any limitation on this. In some embodiments, the substrate is a silicon substrate.

The plurality of photosensitive devices 111 are used to achieve photoelectric conversion. For example, the plurality of photosensitive devices 111 may be photodiodes (PD). In some embodiments, as shown in FIG. 2, the array substrate 110 includes the plurality of photosensitive devices 111. Specifically, the array substrate 110 includes three photosensitive devices 111 in FIG. 2.

Forming the array substrate 110 includes: forming a patterned photoresist layer on a surface of the substrate, using the patterned photoresist layer as a mask to perform an ion implantation process to form the plurality of photosensitive devices 111 in the substrate, removing the patterned photoresist layer, and performing a rapid thermal annealing (RTA) process to form the array substrate 110.

As shown in FIG. 2, the array substrate 110 further includes a second surface 110b opposite to the first surface 110a. A distance between the plurality of photosensitive devices 111 and the first surface 110a is smaller than a distance between the plurality of photosensitive devices 111 and the second surface 110b. Light is incident on the BSI image sensor from the second surface 110b.

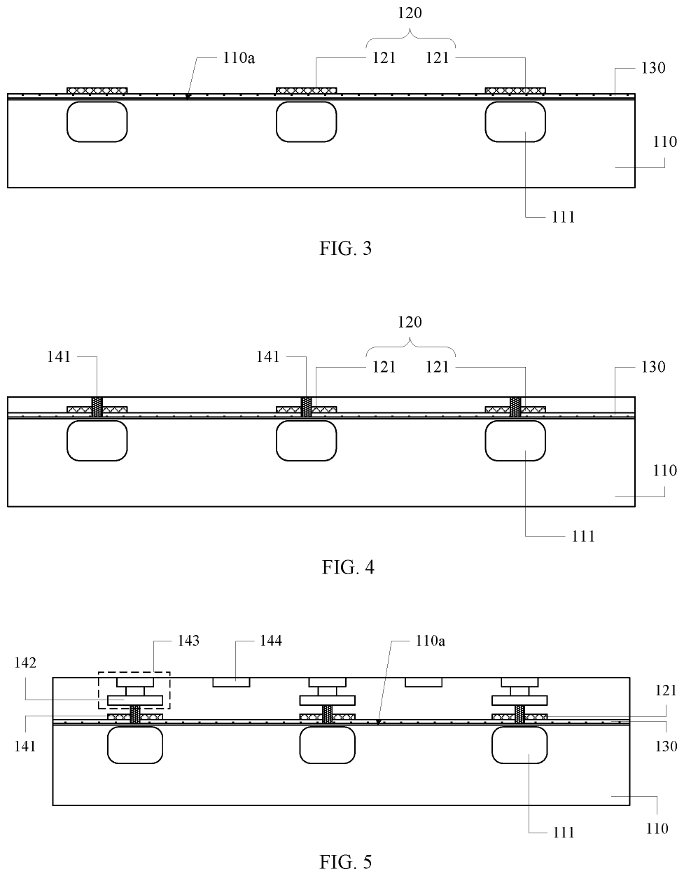

Referring to FIG. 3, a mirror layer 120 is formed over the first surface 110a.

The mirror layer 120 is used to reflect the light transmitted through the array substrate 110.

In some embodiments, the mirror layer 120 includes a plurality of mirror members 121. The plurality of mirror members 121 correspond to the plurality of photosensitive devices 111 in one-to-one correspondence. Each of the plurality of mirror members 121 is provided at a position corresponding to each of the plurality of photosensitive devices 111, which can effectively reduce the crosstalk between adjacent photosensitive devices 111 while ensuring that the transmitted light is reflected to improve the detection efficiency.

A projection of each of the plurality of mirror members 121 on the first surface 110a is consistent with a projection of each of the plurality of photosensitive devices 111 on the first surface 110a. As shown in FIG. 3, the projection of the plurality of mirror members 121 on the first surface 110a coincide with the projection of the plurality of photosensitive devices 111 on the first surface 110a.

In some other embodiments, the projection of each of the plurality of photosensitive devices on the first surface is slightly larger than the projection of each of the plurality of mirror members on the first surface, and the projection of each of the plurality of mirror members on the first surface falls within the projection of each of the plurality of photosensitive devices on the first surface.

In some embodiments, the mirror layer 120 is made of a material including aluminum. That is, the plurality of mirror members 121 of the mirror layer 120 are made of a material including aluminum. The mirror layer 120 being made of a material including aluminum can effectively improve the reflectivity of the mirror layer 120 and control a formation cost of the mirror layer 120.

In some embodiments, the distance between the mirror layer 120 and the first surface 110a ranges from 100 Å to 1000 Å. That is, the distance between the surface of each of the plurality of mirror members 121 facing toward the array substrate 110 and the first surface 110a is in the range of 100 Å to 1000 Å. Controlling the distance between the mirror layer 120 and the first surface 110a can make the mirror layer 120 as close as possible to the plurality of photosensitive devices 111, which can effectively prevent the crosstalk between adjacent photosensitive devices 111.

In some embodiments, as shown in FIG. 3, before forming the mirror layer 120 over the first surface 110a, an isolation layer 130 is formed over the first surface 110a. The mirror layer 120 is formed on a surface of the isolation layer 130.

The isolation layer 130 is used to achieve electrical insulation between the mirror layer 120 and the array substrate 110, and to prevent the material of the mirror layer 120 from diffusing to the array substrate 110.

In some embodiments, the isolation layer 130 is directly formed on the first surface 110a, such that the isolation layer 130 is in contact with the first surface 110a. The mirror layer 120 is directly formed on the surface of the isolation layer 130, such that the isolation layer 130 is in contact with the mirror layer 120.

Making the isolation layer 130 directly contact with the first surface 110a and making the mirror layer 120 directly contact with the isolation layer 130 can make the mirror layer 120 as close as possible to the plurality of photosensitive devices 111, effectively control the transmission range of reflected light, and effectively suppress the crosstalk between adjacent photosensitive devices 111.

In some embodiments, a thickness of the isolation layer 130 ranges from 100 Å to 1000 Å. The thickness of the isolation layer 130 should not be too small, which ensures that the isolation layer 130 block material diffusion of the mirror layer 120. The thickness of the isolation layer 130 should not be too large, which ensures that the mirror layer 120 be as close as possible to the plurality of photosensitive devices 111 to suppress the crosstalk.

In some embodiments, the isolation layer 130 is made of a material including silicon nitride. Further, the isolation layer 130 is made of a material including high-density silicon nitride, which can ensure blocking capability of the isolation layer 130 while minimizing the thickness of the isolation layer 130 to suppress the crosstalk.

For example, forming the mirror layer 120 over the first surface 110a may include: depositing the isolation layer 130 over the first surface 110a, depositing an aluminum mirror film on the isolation layer 130, and patterning the aluminum mirror film through photolithography and etching to form the plurality of mirror members 121 of the mirror layer 120.

Referring to FIGS. 4 to 7, an interconnection structure layer 140 is formed on the mirror layer 120, and the interconnection structure layer 140 is electrically connected to the plurality of photosensitive devices 111.

The interconnection structure layer 140 is used to achieve electrical connection between the array substrate 110 and a subsequent logic processing circuit.

In some embodiments, as shown in FIG. 4, forming the interconnection structure layer 140 on the mirror layer 120 includes: forming a plurality of connectors 141 that pass through the mirror layer 120. The plurality of connectors 141 are electrically connected to the plurality of photosensitive devices 111, and electrically insulated from the plurality of mirror members 121 of the mirror layer 120.

The plurality of connectors 141 are used to achieve the electrical connection between the plurality of photosensitive devices 111 and a subsequent interconnection layer in the interconnection structure layer 140.

In some embodiments, the plurality of connectors 141 are via plugs. As shown in FIG. 4, when forming the plurality of connectors 141 that pass through the mirror layer 120, the plurality of connectors 141 pass through a dielectric material and the plurality of mirror members 121 of the mirror layer 120.

For example, forming the plurality of connectors 141 includes: forming a dielectric material (not shown) on the mirror layer 120 to cover the plurality of mirror members 121 and to extend to the array substrate 110 between adjacent mirror members 121, forming a through-hole (not shown) on each of the plurality of photosensitive devices 111 to pass through the corresponding mirror member 121 and the dielectric material on the mirror member 121, depositing a metal material in the through-hole, and performing a chemical mechanical polishing process to form the via plug in the through-hole. The dielectric material may be an oxide, such as silicon oxide, and the metal material may be tungsten.

As shown in FIG. 5, after forming the plurality of connectors 141, forming the interconnection structure layer 140 on the mirror layer 120 further includes: forming a first interconnection layer 142 that is electrically connected to each of the plurality of connectors 141. For example, forming the first interconnection layer 142 that is electrically connected to each of the plurality of connectors 141 includes: forming a first interconnection member 143 on each of the plurality of connectors 141. The first interconnection member 143 includes the first interconnection layer 142.

The first interconnection member 143 includes multiple interconnection layers. The interconnection layer closest to each of the plurality of photosensitive devices 111 is the first interconnection layer 142. The first interconnection layer 142 is in direct contact with each of the plurality of connectors 141 to achieve the electrical connection.

In some embodiments, the distance between the first interconnection layer 142 and the first surface 110a is greater than 3000 Å. For example, the distance between the first interconnection layer 142 and the first surface 110a ranges from 3000 Å to 6000 Å. The first interconnection layer 142 has the function of the electrical connection. If the distance between the first interconnection layer 142 and the first surface 110a is too small, the distance between the first interconnection layer 142 and each of the plurality of photosensitive devices 111 is too small. A mutual influence between them will affect their respective electrical properties, causing performance degradation of the BSI image sensor formed.

In addition, a dielectric material is also formed on the array substrate 110. Therefore, forming the first interconnection layer 142 also includes: forming the dielectric material (not shown) on the array substrate 110 before forming the first interconnection member 143, and forming the first interconnection member 143 in the dielectric material. The dielectric material covers the plurality of connectors 141.

In some embodiments, the integration of the array substrate and the logic processing circuit is achieved through hybrid bonding during the formation process. The interconnection structure layer 140 is also used to achieve the bonding of the array substrate 110 and the logic substrate. Therefore, forming the interconnection structure layer 140 also includes forming a plurality of first bonding members 144 (i.e., pixel bonding metal).

As shown in FIG. 5, when forming the plurality of first bonding members 144, each of the plurality of first bonding members 144 is formed between adjacent first interconnection members 143. Moreover, the plurality of first bonding members 144 and the plurality of first interconnection members 143 may be located in a same layer and may be formed in a same process.

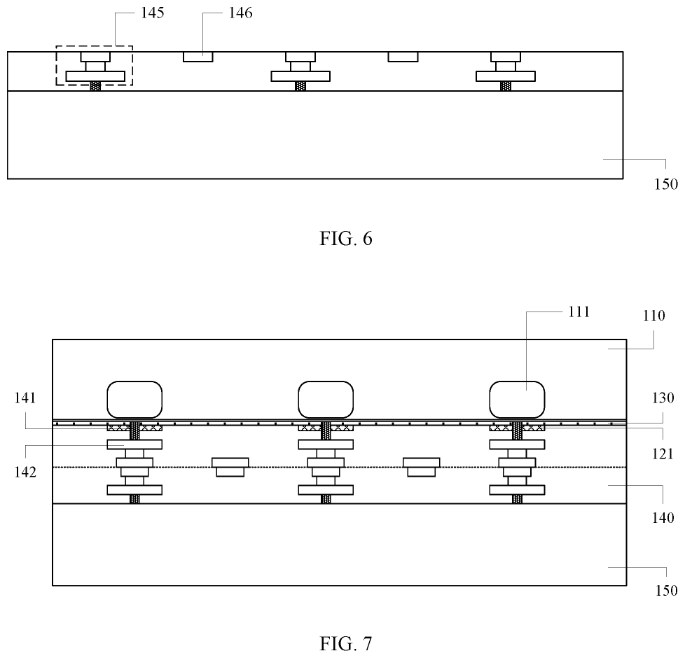

In some embodiments, forming the interconnection structure layer 140 also includes: forming a logic substrate 150 including a logic processing circuit as shown in FIG. 6, and bonding the logic substrate 150 and the array substrate 110 to form the interconnection structure layer 140 as shown in FIG. 7. Therefore, the logic substrate 150 is located on a side of the interconnection structure layer 140 facing away from the array substrate 110, and the logic substrate 150 is electrically connected to the array substrate 110 through the interconnection structure layer 140.

In some embodiments, as shown in FIG. 6, another dielectric material is formed on the logic substrate 150, and a plurality of second interconnection members 145 and a plurality of second bonding members 146 are formed in the dielectric material.

Referring to FIG. 6 and FIG. 7, each of the plurality of second interconnection members 145 is bonded to each of the plurality of first interconnection members 143, and each of the plurality of second bonding members 146 is bonded to each of the plurality of first bonding members 144 to achieve the electrical connection between the logic substrate 150 and the array substrate 110. In addition, the plurality of second interconnection members 145 and the logic substrate 150 are electrically connected through a plurality of connectors (not shown), such that the bonding of the plurality of second interconnection members 145 and the plurality of first interconnection members 143 respectively can also achieve the electrical connection between the logic base 150 and the array substrate 110.

For example, one of the array substrate 110 and the logic substrate 150 is inverted, and the logic substrate 150 and the array substrate 110 is bonded together through hybrid bonding.

In some embodiments, the method further includes: thinning down the array substrate 110. For example, the array substrate 110 also includes the second surface 110b opposite to the first surface 110a (as shown in FIG. 2). The array substrate 110 is thinned down through the second surface 110b. As shown in FIG. 8, after the array substrate 110 is thinned down, an inverted pyramid (i.e., a backside pyramid trench or BST) structure 162 is formed on the second surface 110b of the array substrate 110.

The inverted pyramid structure 162 is used to reduce the light reflectivity of the second surface 110b, increase the light transmittance, and improve the photon efficiency.

For example, when forming the inverted pyramid structure 162, the inverted pyramid structure 162 may be formed by wet etching. The wet etching may be performed using a TMAH solution.

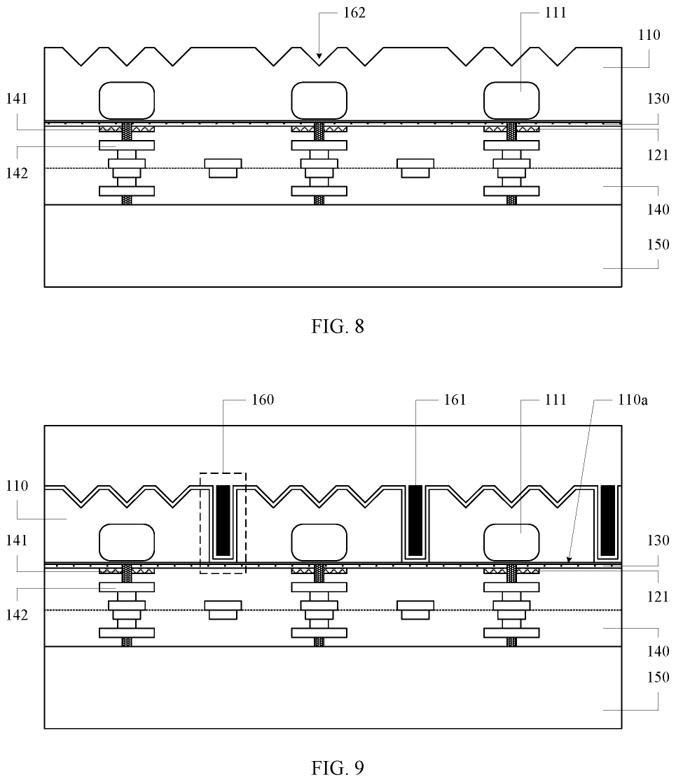

In some embodiments, as shown in FIG. 9, the method further includes: forming an isolation structure 160 between adjacent photosensitive devices 111.

The isolation structure 160 is used to achieve optical isolation between adjacent photosensitive devices 111 to suppress the crosstalk of optical signals.

In some embodiments, on the first surface 110a, the projection of the plurality of mirror members 121 and the projection of a plurality of isolation structures 160 are separated from each other. In a plane parallel to the first surface 110a, the plurality of mirror members 121 and the plurality of isolation structures 160 are vertically separated, thereby preventing the plurality of mirror members 121 from reflecting light to adjacent photosensitive devices 111, and effectively suppressing the crosstalk of optical signals.

For example, the isolation structure 160 is a deep trench isolation (DTI) structure. That is, the isolation structure 160 extends in a direction perpendicular to the first surface 110a.

In some embodiments, the isolation structure 160 includes a conductive material 161. The conductive material 161 is used to load a negative potential to generate holes around the isolation structure 160 to suppress a dark current in an interface state of sidewalls of the isolation structure 160.

For example, forming the isolation structure 160 include: etching the array substrate 110 to form a deep groove in the array substrate 110; depositing a high-K dielectric layer (not shown) on sidewalls of the deep groove, sidewalls of the inverted pyramid structure 162 (as shown in FIG. 8), and the surface of the array substrate 110; depositing another dielectric material to fill in the deep groove and the inverted pyramid structure; removing a part of the dielectric material in the deep groove to form an opening at a position of the deep groove; and filling the opening with the conductive material 161 to form the isolation structure 160.

Correspondingly, the present disclosure also provides a BSI image sensor.

FIG. 9 is a cross-sectional view of an exemplary BSI image sensor according to some embodiments of the present disclosure.

As shown in FIG. 9, the BSI image sensor includes: the array substrate 110 containing the one or more photosensitive devices 111 and including a first surface 110a; the mirror layer 120 (as shown in FIG. 3) disposed at the first surface 110a of the array substrate 110 and electrically insulated from the one or more photosensitive devices 111; and the interconnection structure layer 140 disposed at a side of the mirror layer 120 facing away from the array substrate 110, electrically connected to the one or more photosensitive devices 111, and electrically insulated from the mirror layer 120.

In the embodiments of the present disclosure, the BSI image sensor may be formed by the method of forming the BSI image sensor. Therefore, for the specific technical solution of the BSI image sensor, reference can be made to the foregoing embodiments of the method of forming the BSI image sensor, and detail description will be omitted herein.

The mirror layer 120 is located between the interconnection structure layer 140 and the array substrate 110. The mirror layer 120 is separately provided between the interconnection structure layer 140 and the array substrate 110 to reflect light, thereby improving the photon detection efficiency. Moreover, the mirror layer 120 is electrically insulated from both the interconnection structure layer 140 and the one or more photosensitive devices 111, which can effectively reduce the distance between the mirror layer 120 and the one or more photosensitive devices 111 and can allow the mirror layer 120 to be as close as possible to the one or more photosensitive devices 111. Thus, the crosstalk between adjacent photosensitive devices 111 can be effectively reduced.

The BSI image sensor further includes the isolation layer 130 disposed between the mirror layer 120 and the first surface 110a of the array substrate 110.

The arrangement of the isolation layer 130 can prevent the material of the mirror layer 120 from diffusing into the array substrate 110 and can prevent the material of the mirror layer 120 from adversely affecting the one or more photosensitive devices 111, thereby effectively ensuring the stable performance of the one or more photosensitive devices 111.

The BSI image sensor further includes the isolation structure 160 disposed between adjacent photosensitive devices 111. The isolation structure 160 is located between adjacent photosensitive devices 111. On the first surface 110a, the projection of the plurality of mirror members 121 and the projection of the plurality of isolation structures 160 are separated from each other. Each of the plurality of mirror members 121 and the adjacent isolation structures 120 on both sides form a semi-enveloping structure, which can effectively suppress the crosstalk between adjacent photosensitive devices 111 while improving the light detection efficiency.

The above description of the disclosed embodiments is provided to enable any person skilled in the art to make or use the present application. Various modifications to these embodiments will be readily apparent to those skilled in the art, and the general principles defined herein may be implemented in other embodiments without departing from the spirit or scope of the present disclosure. Therefore, the present disclosure will not be limited to the embodiments shown herein, but is to be accorded the broadest scope consistent with the principles and novel features disclosed herein.

What is claimed is:

1. A backside illuminated (BSI) image sensor, comprising:
an array substrate containing one or more photosensitive devices and including a first surface;
a mirror layer disposed at a side of the first surface of the array substrate and electrically insulted from the one or more photosensitive devices; and
an interconnection structure layer disposed at a side of the mirror layer facing away from the array substrate, electrically connected to the one or more photosensitive devices, and electrically insulated from the mirror layer.

2. The image sensor according to claim 1, further comprising:
an isolation layer disposed between the mirror layer and the first surface of the array substrate.

3. The image sensor according to claim 2, wherein:
the isolation layer is in contact with the first surface of the array substrate.

4. The image sensor according to claim 2, wherein:
the isolation layer is in contact with the mirror layer.

5. The image sensor according to claim 2, wherein:
the isolation layer is made of a material including silicon nitride.

6. The image sensor according to claim 2, wherein:
a thickness of the isolation layer ranges from 100 Å to 1000 Å.

7. The image sensor according to claim 1, wherein:
a distance between the mirror layer and the first surface of the array substrate ranges from 100 Å to 1000 Å.

8. The image sensor according to claim 1, wherein:
the mirror layer is made of a material including aluminum.

9. The image sensor according to claim 1, wherein:
a plurality of photosensitive devices is disposed within the array substrate; and
the mirror layer includes a plurality of mirror members having a one-to-one correspondence to the plurality of photosensitive devices.

10. The image sensor according to claim 9, wherein:
the array substrate further includes a plurality of isolation structures disposed between adjacent photosensitive devices of the plurality of photosensitive devices.

11. The image sensor according to claim 10, wherein:
a projection of the plurality of mirror members on the first surface of the array substrate and a projection of the plurality of isolation structures on the first surface of the array substrate are separated from each other.

12. The image sensor according to claim 1, wherein:
the interconnection structure layer includes a plurality of first interconnection layers and a plurality of connectors, wherein the plurality of connectors are electrically connected to both the plurality of photosensitive devices and the plurality of first interconnection layers respectively, pass through the mirror layer, and are electrically insulated from the plurality of mirror members of the mirror layer.

13. The image sensor according to claim 12, wherein:
the interconnection structure layer further includes a dielectric material; and
the plurality of first interconnection layers are disposed in the dielectric material.

14. The image sensor according to claim 12, wherein:
a distance between the plurality of first interconnection layers and the first surface of the array substrate ranges from 3000 Å to 6000 Å.

15. The image sensor according to claim 1, further comprising:
a logic substrate disposed at a side of the interconnection structure layer facing away from the array substrate, and electrically connected to the array substrate through the interconnection structure layer.

16. A method of forming a backside illuminated (BSI) image sensor, comprising:
forming an array substrate containing one or more photosensitive devices and including a first surface;
forming a mirror layer over the first surface of the array substrate; and
forming an interconnection structure layer over the mirror layer, the interconnection structure layer being electrically connected to the one or more photosensitive devices.

17. The method according to claim 16, further comprising:
forming an isolation layer over the first surface of the array substrate before forming the mirror layer; and
forming the mirror layer over the isolation layer.

18. The method according to claim 16, wherein a plurality of photosensitive devices is disposed within the array substrate; and forming the interconnection structure layer over the mirror layer includes:
forming a plurality of connectors passing through the mirror layer, the plurality of connectors being electrically connected to the plurality of photosensitive devices respectively and being electrically insulated from the plurality of mirror members of the mirror layer; and
forming a plurality of first interconnection layers that are electrically connected to the plurality of connectors.

19. The method according to claim 18, wherein forming the interconnection structure layer over the mirror layer further includes:
forming a dielectric material over the mirror layer;
wherein:
when forming the plurality of connectors passing through the mirror layer, the plurality of connectors pass through the dielectric material and the plurality of mirror members of the mirror layer; and
when forming the plurality of first interconnection layers electrically connected to the plurality of connectors, the plurality of first interconnection layers are formed in the dielectric material.

20. The method according to claim 16, further comprising:
forming a plurality of isolation structures between adjacent photosensitive devices of the one or more photosensitive devices.
